(19) United States
(12) Patent Application Publication
(10) Pub. No.: US 2015/0361583 A1
(43) Pub. Date: Dec. 17, 2015

(54) DUAL AUXILIARY DOPANT INLETS ON EPI CHAMBER

(71) Applicant: Applied Materials, Inc., Santa Clara, CA (US)

(72) Inventors: Jin ZHENG, Singapore (SG); Youqun DONG, Sunnyvale, CA (US)

(21) Appl. No.: 14/730,195

(22) Filed: Jun. 3, 2015

Related U.S. Application Data
(60) Provisional application No. 62/012,067, filed on Jun. 13, 2014.

(51) Int. Cl. C30B 25/14; C30B 29/06

(52) U.S. Cl. CPC C30B 25/14; C30B 29/06

(57) ABSTRACT

The present invention provides methods and apparatus for processing semiconductor substrates with dual or multiple dopant inlets formed at different locations of an epitaxial chamber configured to supply dopant gases toward different locations of the substrate during deposition. In one embodiment, a gas delivery system configured to couple to an epitaxial deposition chamber includes a gas conduit has a first end and a second end configured to dispose in an epitaxial deposition chamber, the first end coupled to a gas panel and a second end branched out to include an auxiliary inner dopant inlet and an auxiliary outer dopant inlet, wherein the auxiliary inner dopant inlet and the auxiliary outer dopant inlet are independently controlled when implementing in the epitaxial deposition chamber.

### CROSS-REFERENCE TO RELATED APPLICATIONS

This application claims benefit of U.S. Provisional Application Ser. No. 62/012,067 filed Jun. 13, 2014 (Attorney Docket No. APPM/20649USL), which is incorporated by reference in its entirety.

### BACKGROUND

1. Field

The present disclosure relates to apparatus and method for processing a semiconductor substrate. More particularly, the present invention relates to apparatus and method for forming an epitaxial layer on a semiconductor substrate.

2. Description of the Related Art

Semiconductor devices are manufactured on silicon and other semiconductor substrates which are made by extruding an ingot from a silicon bath and sawing the ingot into multiple substrates. An epitaxial silicon layer is then formed on the substrate. The epitaxial silicon layer is typically doped with boron and has a dopant concentration of about 1×10¹⁶ atoms per centimeter cube or greater. The material of the epitaxial silicon layer has better controlled properties than the silicon substrate for purpose of forming semiconductor devices therein and thereon. Epitaxial process may also be used during manufacturing of semiconductor devices.

Vapor phase methods, such as chemical vapor deposition (CVD), have been used to manufacture a silicon epitaxial layer on silicon substrates. To grow a silicon epitaxial layer using a CVD process, a substrate is positioned in a CVD epitaxial reactor set to an elevated temperature, for example about 600° C. to 1100° C., and a reduced pressure state or atmospheric pressure. While maintaining the elevated temperature and reduced pressure state, silicon containing gas, such as monosilane gas or dichlorosilane gas along with desired dopant gas, if any, are supplied to the CVD epitaxial reactor and a silicon or doped silicon epitaxial layer is grown by vapor phase growth.

During the deposition process, non-uniform gas flow, heat flow/transmission, or dopant gas concentration across the substrate surface may undesirably result in the resultant silicon epitaxial layer having different film properties at different locations. For example, sheet resistance as measured at an edge of the silicon epitaxial layer may be different from that measured at the center, as heat or process precursor gas may not be distributed uniformly across the substrate surface. In some cases, fluctuation of sheet resistance at different locations of the substrate surface may be significant, which may undesirably create device performance reliability issues, and even damage product yield.

Therefore, there is a need for an apparatus and method for growing an epitaxial layer with good localized film property control while forming the epitaxial layer on a semiconductor substrate.

### SUMMARY

The present invention provides methods and apparatus for processing semiconductor substrates with auxiliary, dual or multiple dopant inlets formed at different locations of an epitaxial chamber configured to supply dopant gases toward different locations of the substrate during deposition. In one embodiment, a gas delivery system configured to couple to an epitaxial deposition chamber includes a gas conduit has a first end and a second end configured to dispose in an epitaxial deposition chamber, the first end coupled to a gas panel and a second end branched out to include an auxiliary inner dopant inlet and an auxiliary outer dopant inlet, wherein the auxiliary inner dopant inlet and the outer gas line are independently controlled when implementing in the epitaxial deposition chamber.

In another embodiment, an apparatus configured to form an epitaxial layer on a substrate includes a gas delivery system coupled to an epitaxial deposition chamber, the gas delivery system comprising a gas conduit has a first end and a second end, the first end coupled to a gas panel and a second end branched out to include an auxiliary inner dopant inlet and an auxiliary outer dopant inlet, wherein the auxiliary inner dopant inlet and the outer gas line are independently controlled when implementing in the epitaxial deposition chamber.

In yet another embodiment, a method for forming a doped silicon epitaxial layer includes supplying a dopant gas into an epitaxial deposition chamber while forming a doped silicon epitaxial layer on a substrate disposed in the epitaxial deposition chamber, wherein the dopant gas is supplied to the epitaxial deposition chamber through an auxiliary inner dopant inlet or an auxiliary outer dopant inlet coupled to the epitaxial deposition chamber, wherein the auxiliary inner dopant inlet is coupled to a first location of the epitaxial deposition chamber and the auxiliary outer dopant inlet is coupled to a second location of the epitaxial deposition chamber.

### BRIEF DESCRIPTION OF THE DRAWINGS

So that the manner in which the above recited features of the present invention can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the invention may admit to other equally effective embodiments.

FIG. 1 schematically illustrates a perspective view of a CVD epitaxial module 100 in accordance with the present invention;

FIG. 2 schematically illustrates a sectional view of one embodiment of process chamber of the modular CVD epitaxial chamber of FIG. 1;

FIG. 3 schematically illustrates a front side of a gas panel module in accordance with addition of dopant inlets incorporated thereto; and

FIG. 4 depicts a simplified schematic drawing of one embodiment of a dopant inlet configuration; and

FIG. 5 depicts a simplified schematic drawing of one embodiment of a dopant inlet configuration coupled to the processing chamber of FIG. 2.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present disclosure provides a gas delivery system with auxiliary, dual or multiple dopant inlets coupled to different regions of a processing chamber. Each dopant inlet may supply the same or different types of dopant gases to different locations of a substrate disposed in the processing chamber during deposition. The auxiliary, dual or multiple dopant inlets may be individually controllable to accommodate forming film layer with different dopant concentration and/or profile control in the resultant silicon layer formed on the substrate.

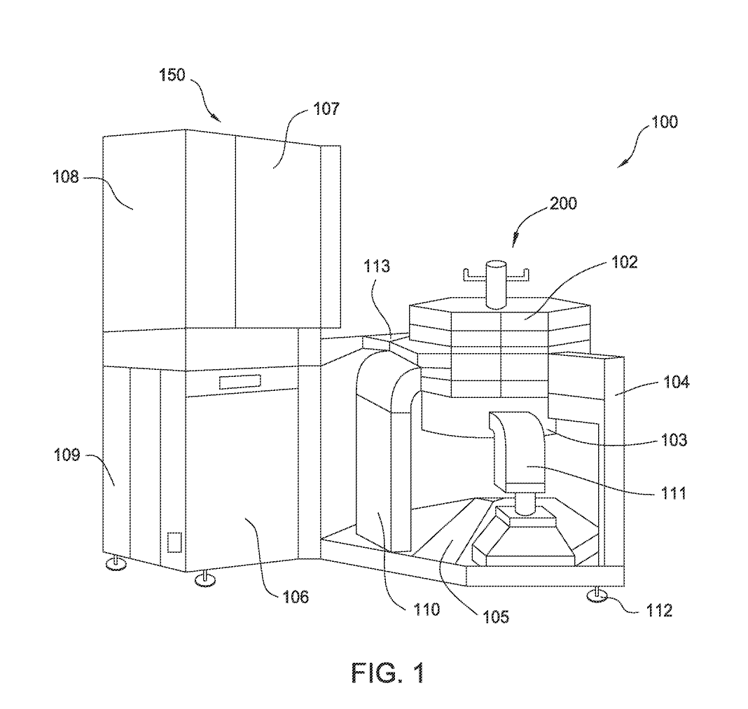

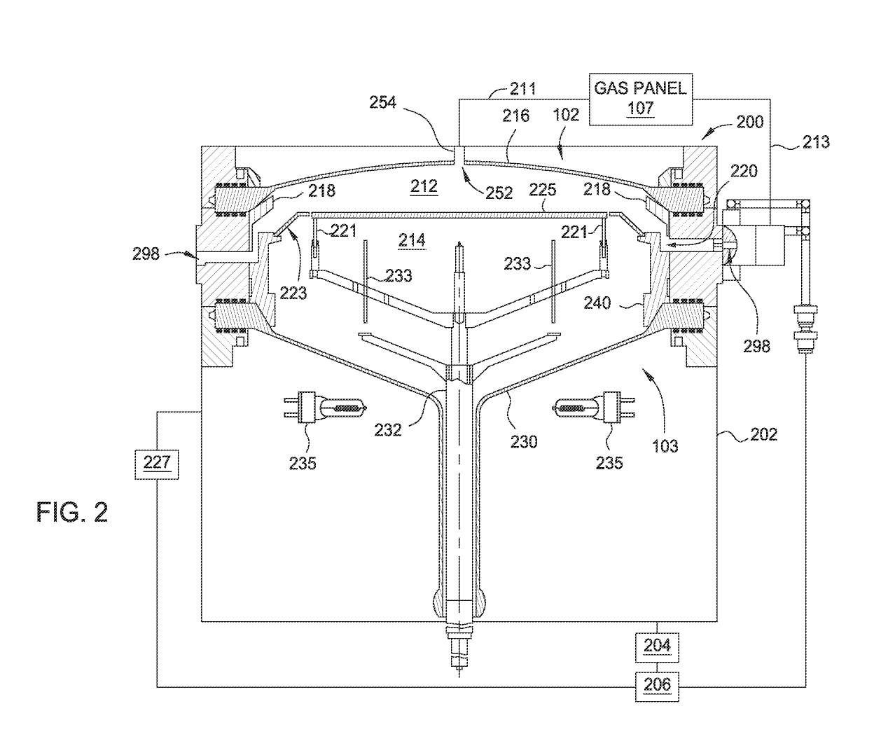

FIG. 1 schematically illustrates a perspective view of a CVD epitaxial module 100 that includes an epitaxial processing chamber 200 incorporated therein. The CVD epitaxial module 100 comprises the epitaxial processing chamber 200 and submodules 150 attached to the epitaxial processing chamber 200. In one embodiment, the epitaxial processing chamber 200 is attached to a support frame 104 configured to support the CVD epitaxial module 100. The epitaxial processing chamber 200 may comprises a chamber body and a chamber lid that hinged to the chamber body, which will be further described later with reference to FIG. 2.

An upper reflector module 102 may be placed on top of the epitaxial processing chamber 200. To suit different processing requirements, various modules may be interchangeably placed on top of the epitaxial processing chamber 200, such as a water cooled reflective plate module with integrated pyrometery, a water cooled reflective plate module with air cooled upper dome, ultra violet (UV) assisted module for lower temperature deposition, and a remote plasma source for cleaning the epitaxial processing chamber 200.

A lower lamp module 103 configured to heat the epitaxial processing chamber 200 during processing is attached to a bottom side of the epitaxial processing chamber 200. In one embodiment, the lower lamp module 103 comprises a plurality of vertically oriented lamps which may be easily replaced from a bottom side of the lower lamp module 103. Additionally, the vertical configuration of the lower lamp module 103 may be cooled using water instead of air, hence, reducing burden of system air cooling. Alternatively, the lower lamp module 103 may also be a lamp module having a plurality of horizontally oriented lamps.

An air cooling module 105 is disposed beneath the epitaxial processing chamber 200 as needed. By positioning the air cooling module 105 underneath the epitaxial processing chamber 200, air cooling ducts 110 and 111 are shortened, thus, reducing total air resistance and allowing the usage of smaller and/or fewer air cooling fans. As a result, the air cooling module 105 is less expansive, quieter and easier to service compared to air cooling systems located at other locations.

One or more of a gas panel module 107, an AC distribution module 106, an electronics module 108 and a water distribution module 109 are positioned adjacent to the epitaxial processing chamber 200.

The gas panel module 107 is configured to provide processing and/or dopant gas to the epitaxial processing chamber 200. The gas panel module 107 is positioned next to the epitaxial processing chamber 200. In one embodiment, the gas panel module 107 is configured to house various process gas delivery components, such as, for example, flow ratio controllers, dopant injects, auxiliary and chlorine inject valves, and mass flow verification components as needed. In one embodiment, dual or multiple auxiliary dopant injects may branch out from the gas panel module 107 to provide individual supply of the same or different dopant gases to different regions of the epitaxial processing chamber 200 as needed. It is noted that the number of the dopant injects branching out from the gas panel module 107 may be as many as needed for different process requirements.

The gas panel module 107 may further comprises different gas panel configurations for various applications, such as, for example, blanket epitaxial, Heterojunction Bipolar Transistor (HBT) epitaxial, selective silicon epitaxial, doped selective SiGe epitaxial, and doped selective SiC epitaxial applications. Different gas panel configurations may be arranged in any manner to meet specific processing requirements.

The gas panel module 107 may include gas panels for delivering carrier gas, such as nitrogen, hydrogen or inert gases, reacting gases and doping gas, such as p-type dopant gases and n-type dopant gases, into the epitaxial processing chamber 200 using different gas path routing so as to maximize the flow efficiency as well as optimization of the film property in the resultant silicon or doped silicon layer.

The electronics module 108 is generally positioned next to the gas panel module 107. The electronics module 108 is configured to control operations of the epitaxial processing chamber 200. The electronics module 108 may comprise a controller for the epitaxial processing chamber 200, a chamber pressure controller, and an interlock board for the gas panel module 107.

The AC distribution module 106 is disposed below the gas panel module 107 and the electronics module 108. The electronics module 108 may comprise a fan controller, a board for electrical power distribution, and a lamp fail board.

The water distribution module 109 is disposed next to the AC distribution module 106. The water distribution module 109 is configured to provide water supply to water cooling units of epitaxial processing chamber 200. The water distribution module 109 may comprise supply and return manifolds, flow limiters and switches, and CDN regulators.

As described above, the support system 104 is supported by several leveling feet 112 having integrated height adjustable casters. The epitaxial processing chamber 200 may be rolled into a desired position when the leveling feet 112 are in a raised up position. Once the epitaxial processing chamber 200 is in position, the leveling feet 112 are lowered and the integrated casters are lifted.

FIG. 2 schematically illustrates a sectional view of the epitaxial processing chamber 200 including the upper reflector module 102 and the lower lamp module 103. In one embodiment, CVD epitaxial processing chamber 200 that may be adapted to benefit from the invention is an EPI CENTURA® near atmospheric CVD System, available from Applied Materials, Inc., of Santa Clara, Calif. The CENTURA® system is a fully automated semiconductor fabrication system, employing a single wafer, multi-chamber, modular design, which accommodates a wide variety of wafer sizes. In addition to the CVD chamber, the multiple chambers may include a pre-clean chamber, wafer orienter chamber, cooldown chamber, and independently operated loadlock chamber. The CVD chamber presented herein is shown in schematic in FIG. 2 is one embodiment and is not intended to be limiting of all possible embodiments. It is envisioned that other atmospheric or near atmospheric CVD chambers can be used in accordance with embodiments described herein, including chambers from other manufacturers.

The CVD epitaxial chamber 200 comprises a chamber body 202, support system 204, and a chamber controller 206. The chamber body 202 includes the upper reflector module 102 and the lower lamp module 103. The upper reflector module 102 includes the area within the chamber body 202 between the upper dome 216 and the substrate 225. The lower lamp module 103 includes the area within the chamber body 202 between a lower dome 230 and the bottom of the substrate 225. Deposition processes generally occur on the upper surface of the substrate 225 within the upper reflector module 102. The substrate 225 is supported by support pins 221 disposed beneath the substrate 225.

An upper liner 218 is disposed within the upper reflector module 102 and is adapted to prevent undesired deposition onto chamber components. The upper liner 218 is positioned adjacent to a ring 223 within the upper reflector module 102. The CVD epitaxial chamber 200 includes a plurality of heat sources, such as lamps 235, which are adapted to provide thermal energy to components positioned within the CVD epitaxial chamber 200. For example, the lamps 235 may be adapted to provide thermal energy to the substrate 225 and the ring 223. The lower dome 230 may be formed from an optically transparent material, such as quartz, to facilitate the passage of thermal radiation therethrough.

The chamber body 202 includes an outer inlet port 298 formed at a side of the CVD epitaxial chamber 200 and a central inlet port 254 formed on a center region of the CVD epitaxial chamber 200 where a center gas line 252 is coupled to. An outer gas line 213 and an inner gas line 211 may be coupled to the outer inlet port 298 and the inner inlet port 254 respectively to deliver gases supplied from the gas panel module 107. Details regarding how the outer gas line 213 and the inner gas line 211 are formed and further coupled to the center gas line 252, which may be further branched out to include auxiliary inner dopant inlet 250a and auxiliary outer dopant inlet 250b (shown in FIG. 5) to be coupled to the CVD epitaxial chamber 200, will be discussed further below. An exhaust port 227 may be coupled to the chamber body 202 to maintain the CVD epitaxial chamber 200 at a desired regulated pressure range as needed. The outer inlet port 298 may be adapted to provide a gas, including doping gas, reacting gas, non-reacting gas, inert gas, or any suitable gas therethrough into the upper reflector module 102 of the chamber body 202. Thermal decomposition of the gas onto the substrate 225 configured to form an epitaxial layer on the substrate 225 is facilitated by the lamps 235.

A substrate support assembly 232 is positioned in the lower lamp module 103 of the chamber body 202. The substrate support assembly 232 is illustrated supporting a substrate 225 in a processing position. The substrate support assembly 232 includes a plurality of support pins 221 and a plurality of lift pins 233. The lift pins 233 are vertically actuatable and are adapted to contact the underside of the substrate 225 to lift the substrate 225 from a processing position (as shown) to a substrate removal position. The components of the substrate support assembly 232 can be fabricated from quartz, silicon carbide, graphite coated with silicon carbide or other suitable materials.

The ring 223 can removably disposed on a lower liner 240 that is coupled to the chamber body 202. The ring 223 can be disposed around the internal volume of the chamber body 202 and circumscribes the substrate 225 while the substrate 225 is in a processing position. The ring 223 can be formed from a thermally-stable material such as silicon carbide, quartz or graphite coated with silicon carbide. The ring 223, in combination with the position of the substrate 225, can separate the volume of the upper reflector module 102. The ring 223 can provide proper gas flow through the upper reflector module 102 when the substrate 225 is positioned level with the ring 223. The separate volume of the upper reflector module 102 enhances deposition uniformity by controlling the flow of process gas as the process gas is provided to the CVD epitaxial chamber 200.

The support system 204 includes components used to execute and monitor pre-determined processes, such as the growth of epitaxial films in the CVD epitaxial chamber 200. The support system 204 includes one or more of the gas modules 107, gas distribution conduits, power supplies, and process control instruments. A chamber controller 206 is coupled to the support system 204 and is adapted to control the CVD epitaxial chamber 200 and support system 204. The chamber controller 206 includes a central processing unit (CPU), a memory, and support circuits. Instructions resident in chamber controller 206 may be executed to control the operation of the CVD epitaxial chamber 200. The CVD epitaxial chamber 200 is adapted to perform one or more film formation or deposition processes therein. For example, a silicon epitaxial growth process may be performed within the CVD epitaxial chamber 200. It is contemplated that other processes may be performed within the CVD epitaxial chamber 200.

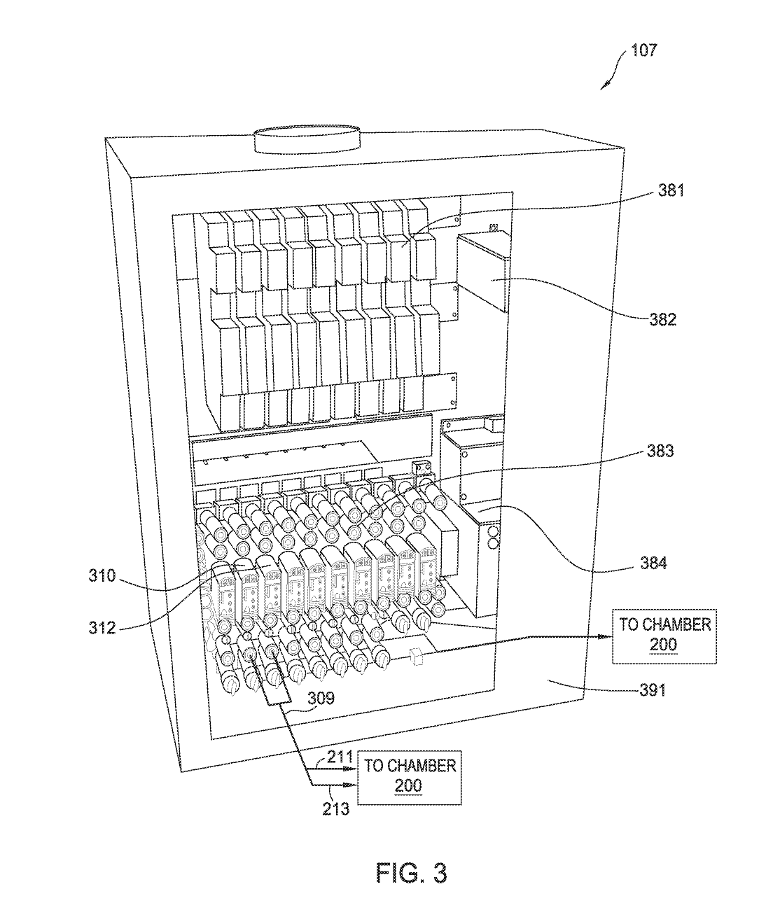

FIG. 3 schematically illustrates a front side of the gas panel module 107 in accordance with one embodiment of the present invention. The gas panel module 107 comprises a plurality of modular components, therefore, providing gases with desired flow path to the CVD epitaxial chamber 200. The gas panel module 107 is enclosed in an enclosure 391. The gas panel module 107 comprises a plurality of gas mixer plates 381 that may supply a mix of gases to the CVD epitaxial chamber 200. The gas panel module 107 is configured to provide alternative and/or mix gases used for deposition, chamber purging and slit valve purging.

The gas panel module 107 further comprises one or more modular process plates 383 configured to provide processing reacting or doping gas to the CVD epitaxial chamber 200. Different modular process plates 383 may be installed in the gas panel module 107 for different processes. The gas panel module 107 further comprises a mass flow verification controller 382 configured to control the flow rate supplied by different modular plates, such as the plates 383 and 381. A flow ratio controller 384 may also be disposed in the gas panel module 107 and configured to control gas flow by ratio.

In one embodiment, the modular process plates 383 may be designed for a variety of deposition processes, for example, blanket deposition, HBT, selective silicon deposition, doped silicon with n-type or p-type dopants, doped selective SiGe, and doped selective SiC applications. Suitable examples for the p-type dopant gas include BH₃, SbH₃ and the like, and suitable examples for the n-type dopant gas include PH₃, AsH₃ and the like.

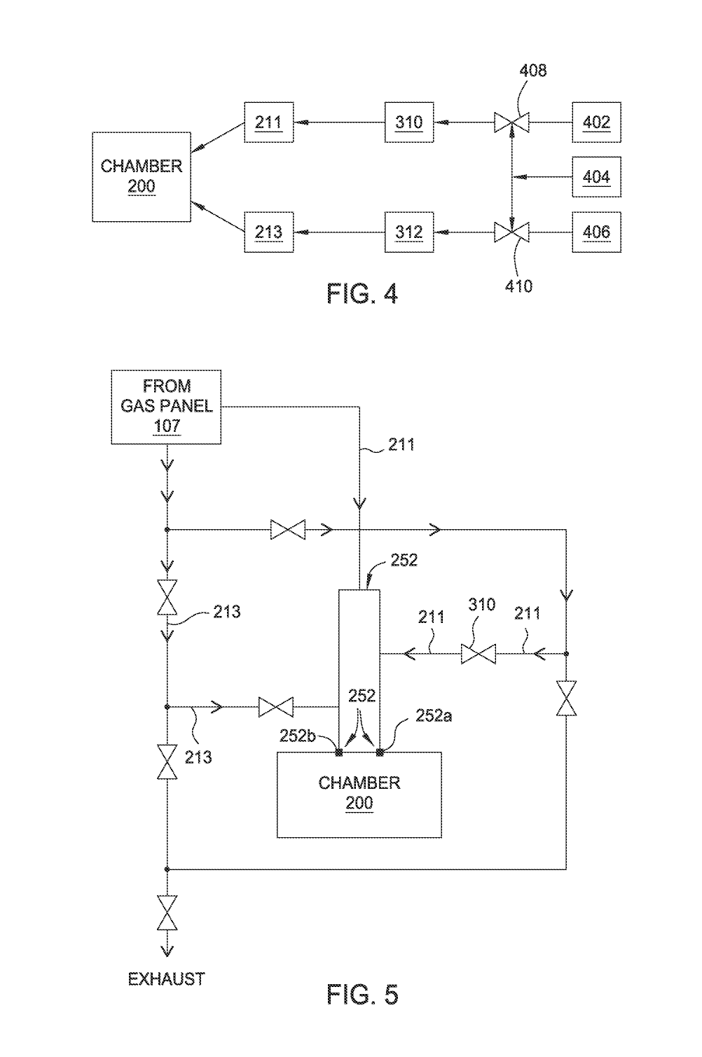

In one embodiment, the gas panel module 107 is further configured to house at least one gas conduit 309 to be further branched out to include one or more gas lines 211, 213, particularly for the inner gas line 211 to further branched out to include the auxiliary inner dopant inlet 250a and the auxiliary outer dopant inlet 250b. Flow through the gas lines 211, 213 are controlled by different gas valves 310, 312 disposed in the modular process plates 383 for supplying additional dopant gases to different locations of the CVD epitaxial chamber 200. In one configuration, the gas lines 211, 213 are arranged as the inner gas line 211 and the outer gas line 213 to provide gases to different locations of the CVD epitaxial chamber 200, which will be described below in greater detail with reference to FIGS. 4-5.

FIG. 4 depicts a simplified schematic drawing of one embodiment of a dopant inlet configuration that may be arranged to couple to the CVD epitaxial chamber 200. A first pair of valves 310, 312 is utilized to facilitate control of the gases supplying through the inner gas line 211 and the outer gas line 213 individually and independently. In on embodiment, the pair of valves 310, 312 is in-line pneumatic valves. Each in-line pneumatic valve 310, 312 utilized to control the gas flow in the inner gas line 211 and the outer gas line 213 is coupled to a lockout valve 408, 410 which is controlled by a respective gate valve 402, 406. In one embodiment, the in-line pneumatic valve 310, 312 may be a normally closed valve, which only opens when both a chamber gate valve 404 and the respective gate valve 402, 406 is actuated open by the controller 206 (depicted in FIG. 2). It is noted that the valves as described herein may be a two-way valve or a three way valve, or other valve suitable for tuning the flow on and off. The chamber gate valve 404 is energized when the CVD epitaxial chamber 200 is in process. The gate valve 402, 406 utilized to control gas flow to the inner gas line 211 and the outer gas line 213 respectively may be energized open when the chamber gate valve 404 is energized during processing. For example, during a deposition process, the chamber gate valve 404 is energized, and subsequently either one of the lockout valve 408, 410 and the gate valves 402, 406 is opened to allow gases flowing through the inner gas line 211 or the outer gas line 213 further to the inner inlet port 254 or outer inlet port 298 formed in the CVD epitaxial chamber 200 as needed.

In one example, when a p-type process is performed in the CVD epitaxial chamber 200 (e.g., a deposition process configured to form a p-type silicon Epi layer on the substrate), the gate valve 402 may be energized, selecting the inner gas line 211 to deliver p-type dopant gas to the CVD epitaxial chamber 200 through the inner gas line 211 to the inner inlet port 254 located at the center portion of the CVD epitaxial chamber 200, thus particularly supplying the p-type dopant gas to a center region of the substrate disposed in the CVD epitaxial chamber 200. In contrast, when a n-type process is configured to perform in the CVD epitaxial chamber 200 (e.g., a deposition process configured to form a n-type silicon Epi layer on the substrate), the gate valve 406 may be energized, selecting the outer gas line 213 to deliver n-type dopant gas to the CVD epitaxial chamber 200 through the outer gas line 213 to the CVD epitaxial chamber 200, thus particularly supplying the n-type dopant gas to a edge of the substrate disposed in the CVD epitaxial chamber 200. It is noted that the inner gas line 211 and the outer gas line 213 may be configured to supply any type of dopant gases, including n-type, p-type, or any suitable dopant gases, to the CVD epitaxial chamber 200 through the inner inlet port 254 or outer inlet port 298 in any manner as needed. Control of the gas flow through the inner gas line 211 and the outer gas line 213 is independently controlled.

FIG. 5 depict another schematic view of a dopant inlet configuration that may be used to couple to the CVD epitaxial chamber 200 of FIG. 2. Similarly, the gas conduit from the gas panel 107 is branched out to include the inner gas line 211 and the outer gas line 213. In the embodiment depicted in FIG. 5, the inner gas line 211 may be laid out in a horizontal direction (when branched out from the gas panel 107) and later configured to turn in a vertical direction, serving as a central gas line 252 to supply gases into the CVD epitaxial chamber 200. As discussed above, the central gas line 252 is then branched out to include the auxiliary inner dopant inlet 250a and auxiliary outer dopant inlet 250b to supply the same or different doping gas to the CVD epitaxial chamber 200. The auxiliary inner dopant inlet 250a may be configured to supply a first type of dopant gas to approximately a center of a substrate disposed in the CVD epitaxial chamber 200 and the auxiliary outer dopant inlet 250b may be configured to supply a second type of dopant gas to approximately a side (or also the center) of a substrate disposed in the CVD epitaxial chamber 200. It is noted that the auxiliary inner dopant inlet 250a and the auxiliary outer dopant inlet 250b may each connect to a respective gas port formed in the CVD epitaxial chamber 200 to supply dopant gases to the CVD epitaxial chamber 200. Alternatively, the auxiliary inner dopant inlet 250a and the auxiliary outer dopant inlet 250b may share a common gas port, such as the central gas inlet port 254 depicted in FIG. 2, to individually or collectively supply gases to the CVD epitaxial chamber 200 which may be individually or simultaneously controlled by the valves formed in the inner gas line 211 and the outer gas line 213. In one embodiment, the dopant gases are individually supply either through the auxiliary inner dopant inlet 250a or the auxiliary outer dopant inlet 250b to the CVD epitaxial chamber 200 one at a time.

In the other hand, the outer gas line 213 may be laid out in a vertical direction (when branched out from the gas panel 107) to supply a second type of dopant gas to the CVD epitaxial chamber 200 through the auxiliary outer dopant inlet 250b. By doing so, dopant gases may be individually supplied at a particularly selected location, either at the center or the edge, approximate to the substrate surface during process so as to tune or adjust local dopant concentration in the resultant film layer formed on the substrate. For example, when a p-type silicon Epi layer is configured to be formed on the substrate, a p-type dopant gas may be additionally supply from the inner gas line 211 through the auxiliary inner dopant inlet 250a supplying to the CVD epitaxial chamber 200 via the central gas inlet port 254. In contrast, when a n-type silicon Epi layer is configured to be formed on the substrate, a n-type dopant gas may be additionally supply from the outer gas line 213 through the auxiliary outer dopant inlet 250b supplying to the CVD epitaxial chamber 200 via the central gas inlet port 254, or a different port formed in the CVD epitaxial chamber 200 as needed. By such configuration, the dopant gas supplied to the substrate surface may be locally adjusted and tuned so that the film dopant concentration at the center region (or at the edge, or in combination) of the film layer may be altered as needed on the substrate. Thus, resultant film layers with different dopant concentration, including different local sheet resistance, conductivity or dopant profile, may be turned or adjusted so as to provide a flexible manufacturing process management or conversion to accommodate different process needs without having to reconfigure the chamber hardware, such as the gas panel.

While the foregoing is directed to embodiments of the present invention, other and further embodiments of the invention may be devised without departing from the basic scope thereof, and the scope thereof is determined by the claims that follow.

What is claimed is:

1. A gas delivery system configured to couple to an epitaxial deposition chamber comprising:
a gas conduit has a first end and a second end configured to dispose in an epitaxial deposition chamber, the first end coupled to a gas panel and a second end branched out to include an auxiliary inner dopant inlet and an auxiliary outer dopant inlet, wherein the auxiliary inner dopant inlet and the auxiliary outer dopant inlet are independently controlled when implementing in the epitaxial deposition chamber.

2. The gas delivery system of claim 1, wherein the auxiliary inner dopant inlet is coupled to couple to an inner inlet port formed in the epitaxial deposition chamber.

3. The gas delivery system of claim 1, wherein the auxiliary outer dopant inlet is coupled to couple to an outer inlet port formed in the epitaxial deposition chamber.

4. The gas delivery system of claim 1, further comprising:
a valve coupled between the gas conduit and the auxiliary inner or outer dopant inlet.

5. The gas delivery system of claim 1, the valve is a three way valve.

6. An apparatus configured to form an epitaxial layer on a substrate comprising:
a gas delivery system coupled to an epitaxial deposition chamber, the gas delivery system comprising:
a gas conduit has a first end and a second end, the first end coupled to a gas panel and a second end branched out to include an auxiliary inner dopant inlet and an auxiliary outer dopant inlet, wherein the auxiliary inner dopant inlet and the auxiliary outer dopant inlet are independently controlled when implementing in the epitaxial deposition chamber.

7. The apparatus of claim 6, wherein the auxiliary inner dopant inlet is coupled to couple to an inner inlet port formed in the epitaxial deposition chamber.

8. The apparatus of claim 6, wherein the auxiliary outer dopant inlet is coupled to couple to an outer inlet port formed in the epitaxial deposition chamber.

9. The apparatus of claim 6, wherein the auxiliary inner dopant inlet is configured to supply a first type of dopant gas to the epitaxial deposition chamber.

10. The apparatus of claim 9, wherein the auxiliary outer dopant inlet is configured to supply a second type of dopant gas to the epitaxial deposition chamber.

11. The apparatus of claim 10, wherein the first type and the second type of dopant gas may be the same or different dopant gases.

12. The apparatus of claim 9, wherein the first type of dopant gas is a p-type dopant gas.

13. The apparatus of claim 10, wherein the second type of dopant gas is a n-type dopant gas.

14. The apparatus of claim 7, wherein the inner inlet port is formed approximate to a center of the epitaxial deposition chamber.

15. The apparatus of claim 8, wherein the outer inlet port is formed approximate to a side of the epitaxial deposition chamber.

16. A method for forming a doped silicon epitaxial layer comprising:
supplying a dopant gas into an epitaxial deposition chamber while forming a doped silicon epitaxial layer on a substrate disposed in the epitaxial deposition chamber, wherein the dopant gas is supplied to the epitaxial deposition chamber through an auxiliary inner dopant inlet or an auxiliary outer dopant inlet coupled to the epitaxial deposition chamber, wherein the auxiliary inner dopant inlet is coupled to a first location of the epitaxial deposition chamber and the auxiliary outer dopant inlet is coupled to a second location of the epitaxial deposition chamber.

17. The method of claim 16, wherein the dopant gas is a n-type dopant gas or a p-type dopant gas.

18. The method of claim 17, the dopant gas is supplied to the epitaxial deposition chamber through the auxiliary inner dopant inlet to the center of the epitaxial deposition chamber when a p-type dopant gas is supplied.

19. The method of claim 17, the dopant gas is supplied to the epitaxial deposition chamber through the auxiliary outer dopant inlet to a side of the epitaxial deposition chamber when a n-type dopant gas is supplied.

20. The method of claim 17, wherein a two way or three way valve is used to control the dopant gas flow from the outer gas line or the auxiliary inner dopant inlet.
